(19) United States
(12) Patent Application Publication
(10) Pub. No.: US 2023/0403903 A1
(43) Pub. Date: Dec. 14, 2023

(54) DISPLAY PANEL, DISPLAY DEVICE, AND INFORMATION PROCESSING APPARATUS

(71) Applicant: Lenovo (Singapore) Pte. Ltd., Singapore (SG)

(72) Inventors: Masato Sugiyama, Kanagawa (JP); Ryoji Satoh, Kanagawa (JP); Limin Xiao, Kanagawa (JP); Moriyuki Tsuchihashi, Kanagawa (JP)

(73) Assignee: Lenovo (Singapore) Pte. Ltd., Singapore (SG)

(21) Appl. No.: 18/311,242

(22) Filed: May 3, 2023

(30) Foreign Application Priority Data
Jun. 13, 2022 (JP) 2022-095127

(51) Int. Cl. H10K 59/35; H10K 59/121; G09G 3/3233; H04N 23/57

(52) U.S. Cl. CPC H10K 59/353; H10K 59/1213; G09G 3/3233; H04N 23/57; G09G 2300/0842; G09G 2300/0465; G09G 2320/0233

(57) ABSTRACT

A display panel includes: a substrate having a surface, and a plurality of pixels; and one or more light emitting elements for each pixel. The plurality of pixels are placed at different positions on the surface of the substrate. The pixels are disposed so that an occupancy rate of the light emitting elements is lower in a first region, which is part of the surface of the substrate, than in a second region, which is a region surrounding the first region and so that in the second region, the occupancy rate increases with a distance from the first region.

### CROSS-REFERENCE TO RELATED APPLICATIONS

This application claims priority to Japanese Patent Application No. 2022-95127 filed on Jun. 13, 2022, the contents of which are hereby incorporated herein by reference in their entirety.

### TECHNICAL FIELD

The present invention relates to a display device that comes with a camera.

### BACKGROUND

Some display devices come with a camera. A camera may be placed on the back surface of a partial region (referred to as a “first region” in this application) of the display region of the screen. Light transmitted through the first region is incident on the camera. The camera captures an image that appears in the incident light. Japanese Translation of PCT International Application Publication No. 2017-521819, for instance, describes a display panel including an OLED array substrate. The display panel implements a translucent function and a display function. The display panel includes a display region, on the rear face of which a photosensitive element including at least one of a camera, a light sensor and a light transmitter is placed.

In the first region, pixels may be thinned out more than in the surrounding region (referred to as a “second region” in this application). This is to increase the transmittance of the first region and thus increase the amount of light incident on the camera. In the first region, however, pixels are thinned out, so the luminance tends to be lower than in the second region. The boundary between the first and second regions may be seen as a boundary line because spatially the luminance abruptly changes there. This boundary line can cause discomfort to the user and reduce subjective image quality.

### SUMMARY

A display panel according to one or more embodiments of the present invention includes: a substrate having a surface, and a plurality of pixels; and one or more light emitting elements for each pixel. The plurality of pixels are placed at different positions on the surface of the substrate. The pixels are disposed so that an occupancy rate of the light emitting elements is lower in a first region, which is part of the surface of the substrate, than in a second region, which is a region surrounding the first region, and so that in the second region, the occupancy rate increases with a distance from the first region.

In the second region of the display panel as stated above, the light emitting elements located farther from the first region may have a larger size.

In the second region of the display panel as stated above, the pixels located farther from the first region may have a higher density.

A display panel according to one or more embodiments of the present invention includes: a substrate having a surface, and a plurality of pixels; and one or more light emitting elements and a drive element in each pixel, the drive element being configured to supply current to the one or more light emitting elements. The plurality of pixels are placed at different positions on the surface of the substrate. The pixels are placed so that an occupancy rate of the light emitting elements is lower in a first region, which is part of the surface of the substrate, than in a second region, which is a region surrounding the first region, and the drive elements for the light emitting elements are configured to supply more current for the light emitting elements of the pixels located in the first region than for the light emitting elements of the pixels located in the second region.

In the display panel as described above, an aspect ratio of a width to a length of the drive elements for the light emitting elements of the pixels located in the first region may be greater than the aspect ratio of the drive elements for the light emitting elements of the pixels located in the second region.

In the display panel as described above, the light emitting elements may include organic light emitting diodes.

A display device according to one or more embodiments of the present invention includes: the display panel as described above; and an imaging unit configured to capture an image on a back surface of the first region.

An information processing apparatus according to one or more embodiments of the present invention includes: the display device as described above; and a control unit configured to cause the display device to output an image in accordance with a data signal indicating a luminance value for each pixel and cause the imaging unit to capture an image.

One or more embodiments of present invention mitigate or eliminate degradation in image quality.

### BRIEF DESCRIPTION OF THE DRAWINGS

FIG. 1 is a front view of an example configuration of a display device according to one or more embodiments.

FIG. 2 is a side view of an example configuration of the display device according to one or more embodiments.

FIG. 3 is a circuit diagram illustrating the pixel circuit according to one or more embodiments.

FIG. 4 is a perspective view illustrating an example configuration of the light-emitting element driving transistor according to one or more embodiments.

FIG. 5 explains a first distribution example of the pixels according to one or more embodiments.

FIG. 6 explains a second distribution example of the pixels according to one or more embodiments.

FIG. 7 is a front view of an example configuration of a display device according to one or more embodiments.

FIG. 8 illustrates an example of the signal voltage dependence that a drive current has.

### DETAILED DESCRIPTION

### First Example

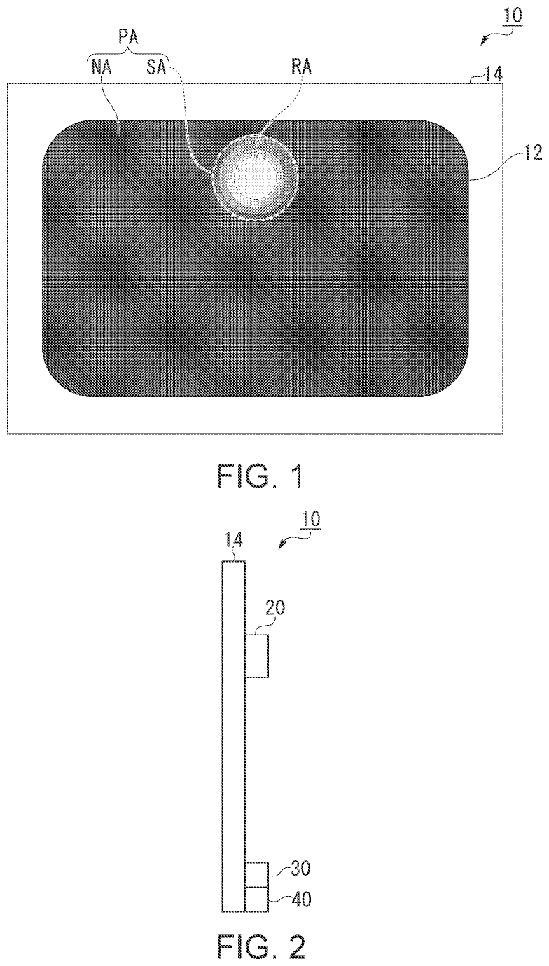

The following describes embodiments of the present invention, with reference to the drawings. First, the following describes a first example according to one or more embodiments. FIG. 1 is a front view of an example configuration of a display device 10 according to one or more embodiments. FIG. 2 is a side view of an example configuration of the display device 10 according to one or more embodiments.

The display device 10 includes a display panel 12, a bezel 14, a camera 20, a controller 30, and an input interface 40.

The display panel 12 has a flat plate shape. The display panel 12 has a thickness that is sufficiently smaller than its width or height. The shape of the front face of the display panel 12 is substantially rectangular. In the example of FIG. 1, the horizontal width is greater than the vertical height. The display panel 12 includes a plurality of pixels and a substrate. These pixels are placed at different positions on the surface of the substrate so as not to overlap each other. The distribution of the luminance of individual pixels allows an image to be displayed so that the user can view it from the front face of the display panel 12. The display panel 12 is supported by the bezel 14. The bezel 14 surrounds the perimeter of the front face of the display panel 12. This configuration exposes substantially the entire front face of the display panel 12. In the present application, the term “image” refers to any one of visible patterns, figures, letters, symbols, etc., or a combination of a plurality of any of them.

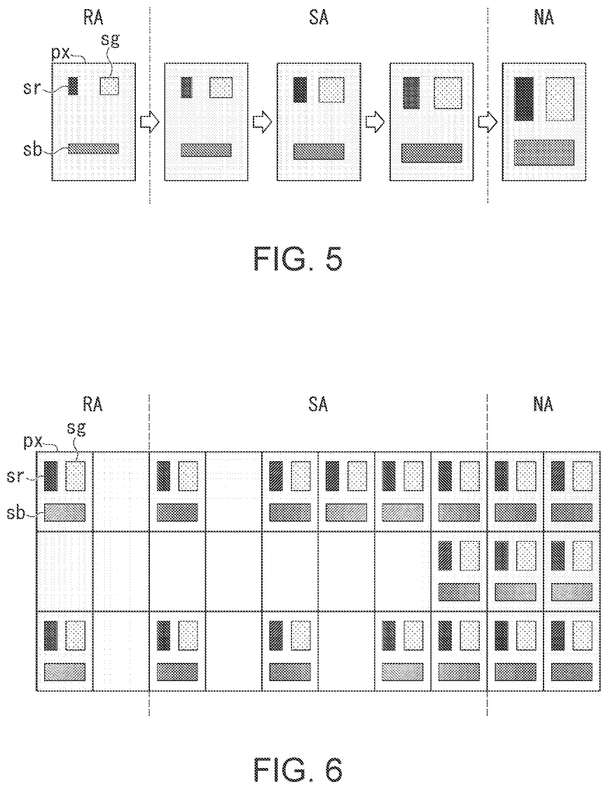

The pixels each include one or more light emitting elements. FIGS. 5 and 6 illustrate an example where each pixel has three light emitting elements. The three light emitting elements emit red, blue, and green light. Color and brightness of each pixel are represented by a combination of the luminance of these light emitting elements. For instance, the light emitting elements are organic light emitting diodes (OLED). The substrate includes a transparent and insulating material. The surface of the light emitting elements may be covered with a protective film made of a transparent material. Examples of the materials for the substrate and protective film include glass and plastic. Using an insulating material as these materials allows the substrate and protective film to function as an insulating material.

For instance, a typical size of the display panel 12 is 12 to 16 inches in diagonal length. For instance, the thickness of the display panel 12 is 0.3 to 5 mm. For instance, the aspect ratio of the screen is 16:9 to 3:2. For instance, the number of pixels placed on the display panel 12, that is, the resolution is 1280×720 to 3840×2160.

The surface of the display panel 12 has a first region RA and a second region PA. The first region RA occupies part of the surface of the display panel 12. The second region PA is the remaining region of the surface of the display panel 12 other than the first region PA. Typically, the size of the first region RA is sufficiently smaller than the size of the second region PA. In the example of FIG. 1, the first region RA is located at a position that is displaced from the center toward one of the long sides (upward) of the surface of the display panel 12. The first region RA is approximately circular. For instance, the diameter of the first region RA is ⅛ to 1/20 of the length (height) of the short sides of the display panel 12. In the following description, the direction of the long sides of the surface of the display panel 12 is referred to as the “horizontal” or “x direction.” The direction of the short sides of the plane is referred to as the “vertical” or “y-direction.” The thickness direction of the display panel 12 is referred to as the “thickness direction” or “z direction.”

The first region RA and second region PA differ in the occupancy rate of the light emitting elements included in each pixel. The occupancy rate of the light emitting elements corresponds to the ratio of the area of the light emitting elements to the area of the corresponding region. The corresponding region means the region in which pixels having the light emitting element are placed. FIG. 1 indicates the occupancy rates of the light emitting elements by the color density. A darker portion indicates a higher occupancy rate of the light emitting elements, and a brighter portion indicates a lower occupancy rate of the light emitting elements. The occupancy rate of the light emitting elements in the first region RA is lower than the occupancy rate of the light emitting elements in the second region PA. In the first region RA, the occupancy rate of light emitting elements and the density of pixels are spatially uniform. In the present application, the occupancy rate of the light emitting elements in the first region RA is referred to as a “first occupancy rate.” The first occupancy rate corresponds to a minimum occupancy rate on the surface of the display panel 12.

In the second region PA, the occupancy rate of light emitting elements varies with position. The pixels in the second region PA are arranged so that the occupancy rate of light emitting elements is higher with a greater distance from the periphery of the first region RA. At a sufficient distance from the first region RA, the occupancy rate of the light emitting elements is maximum on the surface of the display panel 12. The occupancy rate of light emitting elements and the density of pixels at this location are spatially uniform. In the present application, the occupancy rate of the light emitting elements at a position sufficiently distant from the first area RA is referred to as a “second occupancy rate.” The second occupancy rate corresponds to the occupancy rate of standard light emitting devices representative of the display panel 12. The second occupancy rate is significantly higher than the first occupancy rate. For instance, the second occupancy rate is 2 to 10 times the first occupancy rate.

In the present application, a region of the second region PA where the light emitting elements have a constant second occupancy rate is referred to as a “standard region NA.” A region of the second region PA where the light emitting elements do not have the second occupancy rate is referred to as a “transition region SA.” In the transition region SA, the occupancy rate of light emitting elements can vary with position. In the first region RA and standard region NA, pixels are placed at regular intervals in the horizontal and vertical directions. In FIG. 1, the transition region SA surrounds the first region RA. The standard region NA surrounds the transition region SA. In the transition region SA, the occupancy rate of light emitting elements changes from the boundary with the first region RA to the boundary with the standard region NA so that the occupancy rate gets closer from the first occupancy rate to the second occupancy rate with an increase in distance from the boundary with the first region RA.

For instance, the pixels in the transition region SA may be arranged so that the occupancy rate of light emitting elements varies from the first occupancy rate to the second occupancy rate linearly with a distance from the boundary with the first region RA. The pixels may be arranged so that the occupancy rate of light emitting elements varies nonlinearly with a distance from the boundary with the first region RA. In that case, the rate of change of the occupancy rate of the light emitting elements relative to the distance from the boundary with the first region RA may be zero at each of the boundaries with the first region RA and the standard region NA. This moderates the spatial variation in luminance between the first region RA and the standard region NA. Examples of pixel distribution are described later.

The camera 20 is placed on the back surface of the display panel 12. The camera 20 receives light that has passed through the first region RA of the display panel 12, and captures an image that appears in the received light. The camera 20 outputs an image signal indicating the captured image to an external device. The camera 20 includes an imaging element and an objective lens. The imaging element is placed on an imaging plane of the camera to capture an image appearing in light incident on the imaging plane, and generate an image signal indicating the captured image. The objective lens is placed at a position facing the back surface of the first region RA, and converges the light that has passed through the first region RA onto the imaging plane.

The controller 30 causes the display panel 12 to display an image indicated by a data signal input from the input interface 40. The controller 30 may be a microcomputer with arithmetic circuitry. The arithmetic circuitry may be either a central processing unit (CPU) or an application specific integrated circuit (ASIC), for example. The controller 30 supplies electric power corresponding to the luminance value of each light emitting element of the pixel indicated by the data signal, and causes the light emitting element(s) of the corresponding pixel to emit light with the luminance indicated by the luminance value.

For instance, the data signal has a color signal value in accordance with the RGB color system for each pixel. The color signal value in accordance with the RGB color system has luminance values for red, blue, and green. A data signal representing a moving image indicates a luminance value for each pixel in each frame constituting the moving image. In synchronization with the data signal, the controller 30 instructs the power supply to a pixel at the time corresponding to the pixel in each frame, and generates a gate signal to stop the power supply to other pixels. The controller 30 determines the time to emit light for each pixel according to the frame rate indicated by the data signal and the position of the pixel in the display panel 12. The controller 30 outputs a data signal and a gate signal for each pixel. In each pixel, the light emitting element(s) emit light with the luminance indicated by the luminance value indicated by the data signal at the time indicated by the gate signal input from the controller 30.

The input interface 40 receives a data signal from an external device separate from the display panel 12 and outputs the input data signal to the controller 30. The input interface 40 connects to the external device by wire or wirelessly so that various types of signals can be input/output. For the input interface 40, DisplayPort (registered trademark), Miracast (registered trademark), or other transmission methods specified in their standard may be used.

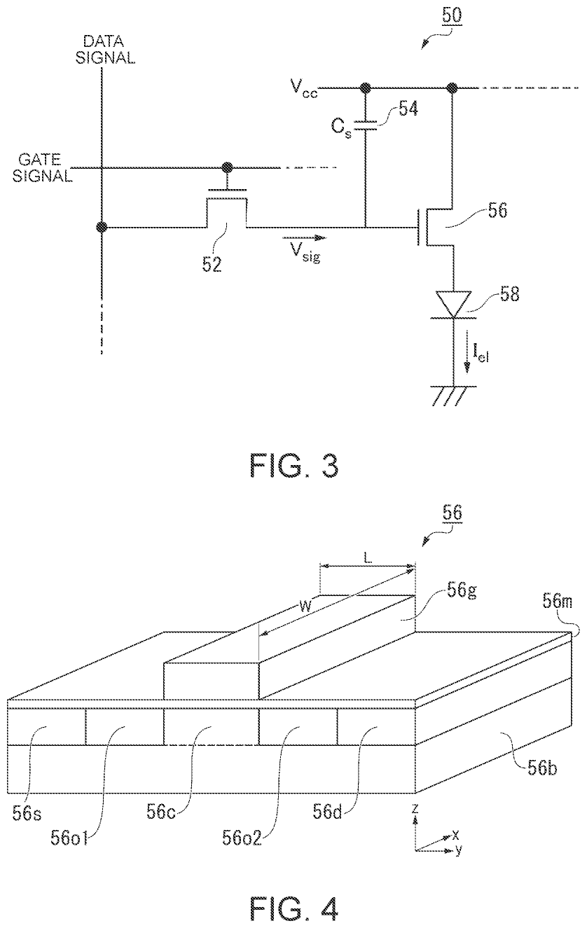

The following describes an example of the pixel circuit according to one or more embodiments. FIG. 3 is a circuit diagram illustrating the pixel circuit 50 according to one or more embodiments. In the example in FIG. 3, a light emitting element 58 is an organic light-emitting diode (OLED). The display panel 12 (FIG. 1) includes the pixel circuit 50 for each light emitting element 58. The pixel circuit 50 emits light from the light emitting element 58 in accordance with the gate and data signals input from the controller 30 (FIG. 1). The data signal indicates the luminance value for each of the light emitting elements 58. The gate signal indicates whether or not light emission is required for each pixel.

The pixel circuit 50 includes a signal writing transistor 52, a capacitive element 54, a light-emitting element driving transistor 56, and a light emitting element 58.

The signal writing transistor 52 supplies electric power, which corresponds to the luminance value indicated by the data signal, to the light-emitting element driving transistor 56 at the time indicated by the gate signal. For instance, the signal writing transistor 52 is a thin film transistor. The data signal and the gate signal are input to the source electrode and the gate electrode of the signal writing transistor 52, respectively. The data signal is a multilevel electrical signal having a signal voltage V_{sig} corresponding to the luminance value. The gate signal is a binary electrical signal that has either a high voltage or a low voltage. Depending on a high voltage or low voltage, the gate signal indicates whether or not light emission is required. When the voltage applied to the gate signal is high, the signal writing transistor 52 conducts the data signal input to the source electrode to the drain electrode, and when the voltage applied to the gate signal is low, the signal writing transistor 52 blocks the data signal input to the source electrode.

The capacitive element 54 has an electric capacity Cₛ, and has one end connected to the power supply and the other end connected to the drain electrode of the signal writing transistor 52 and the gate electrode of the light-emitting element driving transistor 56. For instance, the capacitive element 54 includes an interlayer insulating film in the pixel circuit. A signal voltage V_{sig} is applied to the other end of the capacitive element 54. The capacitive element 54 therefore holds the potential difference V_{cc}−V_{sig} between the power supply voltage V_{cc} and the signal voltage V_{sig}.

The light-emitting element driving transistor 56 has a source electrode connected to the power supply, a gate electrode connected to the drain electrode of the signal writing transistor, and a drain electrode connected to the light emitting element 58. For instance, the light-emitting element driving transistor 56 is a thin film transistor. When the signal writing transistor 52 applies the signal voltage V_{sig} to the gate electrode of the light-emitting element driving transistor 56, the light-emitting element driving transistor 56 supplies a current Iₑₗ corresponding to the potential difference V_{cc}−V_{sig} to the light emitting element. Thus, the luminance value indicated by the data signal is converted into the current Iₑₗ to be supplied to the light emitting element.

The light emitting element 58 has an anode and a cathode at one end and the other end. The light emitting element 58 emits light with a luminance corresponding to the current flowing from the one end to the other end (current drive). To the anode of the light emitting element 58, the drain electrode of the light-emitting element driving transistor 56 is connected. The cathode of the light emitting element 58 is grounded. The light emitting element 58 consumes power supplied via the current Iₑₗ from the light-emitting element driving transistor 56. Thus, the light emitting element 58 emits light with a luminance corresponding to the luminance value indicated by the data signal.

Next, the following describes an example configuration of the light-emitting element driving transistor 56 according to one or more embodiments. FIG. 4 is a perspective view illustrating an example configuration of the light-emitting element driving transistor 56 according to one or more embodiments. The light-emitting element driving transistor 56 includes a glass substrate 56b, a source region 56s, a light doped drain (LDD) region 56o1, a channel region 56c, a LDD region 56o2, a drain region 56d, a gate insulating film 56m, and a gate electrode 56g. The source region 56s, LDD region 56o1, channel region 56c, LDD region 56o2, and drain region 56d are formed on the surface of the glass substrate 56b, and have a same thickness. The source region 56s, LDD region 56o1, channel region 56c, LDD region 56o2, and drain region 56d each have a rectangular shape with one side longer than the other, and are arranged in this order in their width direction.

In the following description, the longitudinal direction of these source region 56s, LDD region 56o1, channel region 56c, LDD region 56o2, and drain region 56d is referred to as x direction, the direction in which they are arranged side by side is referred to as y direction, and their stacking direction on the glass substrate 56b is referred to as z direction. The opposite direction of y direction is referred to as a reverse y direction. The light-emitting element driving transistor 56 further has a source electrode and a drain electrode. These source and drain electrodes (not illustrated) are connected to the source region 56s and drain region 56d, respectively.

A polysilicon film is formed on the surface of the glass substrate 56b. The source region 56s and the drain region 56d are doped regions, in which the polysilicon film is heavily doped with impurities. The LDD regions 56o1 and 56o2 are doped regions, in which the polysilicon film is lightly doped with impurities. The channel region 56c is a region of the polysilicon film that is not doped with impurities.

The gate electrode 56g is stacked on the surface of the channel region 56c in the z direction with the gate insulating film 56m interposed therebetween. The gate insulating film 56m covers the entire surface of the source region 56s, LDD region 56o1, channel region 56c, LDD region 56o2, and drain region 56d. The LDD regions 56o1 and 56o2 mitigate the electric field concentration at the source/drain edges, thus preventing hot carrier degradation of the TFT and reducing off-current. The LDD regions 56o1 and 56o2 are not essential and may be omitted.

With this configuration, when the signal voltage V_{sig} applied to the gate electrode 56g exceeds a certain value, the transistor becomes conductive from the source electrode to the drain electrode. The higher the signal voltage V_{sig}, the higher the conductivity from the source electrode to the drain electrode. In the example of FIG. 8, when the potential difference between the source electrode and the drain electrode is set to a constant power supply voltage V_{cc}, the current Iₑₗ does not flow through the light-emitting element 58 when the signal voltage V_{sig} is from 0 V to V_{cc}−Vₜh. Vₜₕ indicates the threshold voltage of the light-emitting element driving transistor 56. The power supply voltage V_{cc} is preset to be higher than the threshold voltage Vₜᵢ. As the signal voltage V_{sig} exceeds V_{cc}−Vₜₕ and the signal voltage V_{sig} increases, the current Iₑₗ in the light emitting element 58 increases.

Specifically, the current Iₑₗ is proportional to the square of the difference (V_{cc}−V_{sig})−Vₜₕ among the power supply voltage V_{cc}, the signal voltage V_{sig} and the threshold voltage Vₜₕ, as shown in equation (1). In equation (1), p denotes the mobility of the light-emitting element driving transistor 56, C_{OX} denotes the unit capacitance of the gate insulating film 56m, L denotes the length of the gate electrode 56g, and W denotes the width of the gate electrode 56g. The length L corresponds to the element size of the light-emitting element driving transistor 56 in y direction, the direction of the current Iₑₗ. The width W corresponds to the element size of the light-emitting element driving transistor 56 in x direction orthogonal to the direction of the current Iₑₗ. The current Iₑₗ is inversely proportional to the length L and proportional to the width W.

$$\\ \begin{matrix}[ Math . 1 ] & \\ {I}_{el} = \frac{1}{2} μ {C}_{OX} \frac{W}{L} {\{ ( {V}_{CC} - {V}_{sig} ) - {V}_{th} \}}^{2} & ( 1 )\end{matrix}$$

Next, the following describes an example of the pixel distribution according to one or more embodiments. FIG. 5 explains a first distribution example of the pixels according to one or more embodiments. FIG. 5 illustrates the first distribution example, in which the pixels px are distributed in the left-right direction from the first region RA to the standard region NA via the transition region SA. Each pixel px includes three light emitting elements sr, sg, and sb. These light emitting elements sr, sg, and sb emit red, blue, and green light, respectively. In the first distribution example, pixels located farther from the first region RA in the transition region SA have larger light emitting elements. The sizes of the light emitting elements sr, sg, and sb of pixels px in the first region RA are significantly smaller than the sizes of the light emitting elements sr, sg, and sb of pixels px in the second region PA. In the transition region SA, the sizes of the light emitting elements sr, sg, and sb in each pixel px increases with a distance from the first region RA.

Thus, in the first distribution example, the pixels are arranged so that the occupancy rate of the light emitting elements is higher at positions further away from the first region RA in accordance with the sizes of the light emitting elements sr, sg, and sb. In the first distribution example, the density of the pixels is constant, regardless of whether they are arranged in the first region RA, the transition region SA, or the standard region NA. Such regular arrangement of the pixels at equal intervals allows the controller 30 to easily determine the time at which the light emitting elements of the individual pixels emit light.

FIG. 6 explains a second distribution example of the pixels according to one or more embodiments. FIG. 6 illustrates the second distribution example, in which the pixels px are distributed in the left-right direction from the first region RA to the standard region NA via the transition region SA. In the second distribution example, individual pixels are arranged in the transition region SA so that their density increases with a distance from the first region PA. The density of pixels in the first region RA is significantly smaller than the density of pixels in the second region PA.

Thus, in the second distribution example, the pixels are arranged so that the occupancy rate of the light emitting elements is higher at positions further away from the first region RA in accordance with the density of the pixels. In the second distribution example, the sizes of the light emitting elements sr, sg, and sb that the pixels have are the same, regardless of whether they are arranged in the first region RA, the transition region SA, or the standard region NA. Thus, this configuration does not require the production stage of the display panel 12 to prepare pixels having light emitting elements of different sizes in advance, and to determine the arrangement of individual pixels based on the size of the light emitting elements.

### Second Example

Next, the following describes a second example according to one or more embodiments. The following description mainly focuses on differences from the above-described embodiments. Unless otherwise specified, like numbers indicate like components common to the above-described embodiments, and the description thereof is incorporated.

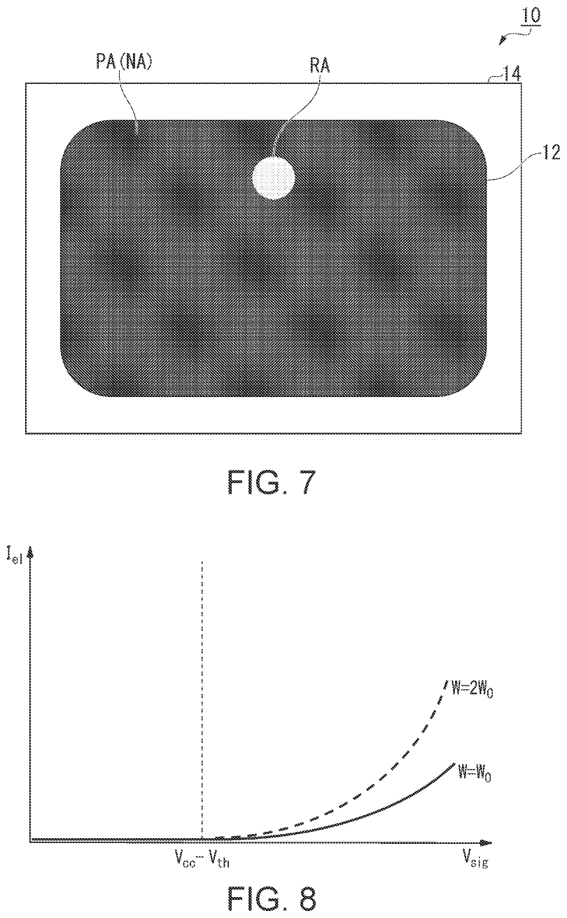

FIG. 7 is a front view of an example configuration of a display device 10 according to one or more embodiments.

The surface of the display panel 12 has a first region RA and a second region PA. The occupancy rate of the light emitting elements in the first region RA is a first occupancy rate, and the occupancy rate of the light emitting elements in the second region PA is a second occupancy rate. The second region PA has a standard region NA and does not have a transition region SA. The occupancy rate of the light emitting elements in the first region RA is significantly lower than the occupancy rate of the light emitting elements in the second region PA. This means that the occupancy rate of the light emitting elements changes abruptly across the boundary between the first region RA and the second region PA.

In one or more embodiments, the light-emitting element driving transistors 56 for the light emitting elements of the pixels located in the first region RA supply more current to these light emitting element than the current supplied to the light emitting elements 58 of the pixels located in the second region PA for a certain luminance value. For the certain luminance value, the light emitting elements 58 of the pixels located in the first region RA emit light with higher luminance than the light emitting elements 58 of the pixels located in the second region PA. This reduces or eliminates the luminance difference caused by the difference in the occupancy rate of the light emitting elements 58 between the first region RA and the second region PA. For instance, the parameters of the light-emitting element driving transistors 56 may be set so as to supply the current from the individual light-emitting element driving transistors 56 to the corresponding light emitting elements 58 so that, for a certain luminance value, the product of the occupancy rate of the light emitting elements 58 in the first region RA and the luminance is equal to the product of the occupancy rate of the light emitting elements 58 in the second region PA and the luminance.

As shown in equation (1), the current Iₑₗ flowing through the light emitting element 58 depends on the mobility p, unit capacitance C_{OX}, width W and length L as parameters of the light-emitting element driving transistor 56 under a constant signal voltage V_{sig}. Of these parameters, width W and length L are relatively easy to adjust. The width W and length L characterize the element size of the light-emitting element driving transistor 56. In the example of FIG. 8, the width W is doubled from W₀ to 2W₀, thus doubling the current Iₑₗ. Shortening the length L can also increase the current Iₑₗ.

For instance, one or more embodiments may be configured so that the light-emitting element driving transistors 56 with different aspect ratios W/L are used for between the light emitting elements of the pixels located in the first region RA and the light-emitting elements of the pixels located in the second region PA. In this case, the aspect ratio W/L in the first region RA is set to be larger than the aspect ratio W/L in the second region PA.

In one or more embodiments also, the occupancy rate of the light emitting elements may be set using either the size of the light emitting element(s) in each pixel or the density of the pixels. That is, the size of the light emitting element(s) for each pixel in the first region RA may be smaller than the size of the light emitting element(s) for each pixel in the second region PA. The density of pixels in the first region RA may be lower than the density of pixels in the second region PA.

### Modified Examples

Next, the following describes modified examples of the above embodiments. Features of these embodiments may be combined, and some may be omitted or modified. For instance, the second region PA of the display panel 12 according to the second example may include a transition region SA as in the first example. In this transition region SA, the pixels are arranged so that the occupancy rate of light emitting elements is higher with a greater distance from the periphery of the first region RA, and the parameters of the light-emitting element driving transistors for the light emitting elements of these pixels are set so that the current supplied to these light emitting elements of the pixel is reduced. Then, the occupancy rate of the light emitting elements in the first region RA is significantly lower than the occupancy rate of the light emitting elements in the standard region NA, and the parameters of the light-emitting element driving transistor for the light emitting elements are set so that the current supplied to the light emitting elements in the first region RA is significantly more than the current supplied to the light emitting elements in the standard region NA. The parameters of the light-emitting element driving transistors 56 may be set so that, for a certain luminance value, the product of the occupancy rate of the light emitting elements 58 and the luminance is the same in the entire first region RA and second region PA.

In the above-described embodiments, the display device 10 may include an imaging element, instead of the camera 20, as an example of the imaging unit. The imaging element is placed on the back surface of the first region RA and captures an image appearing in the light transmitted through the first region RA. The imaging element generates a data signal indicating the captured image and outputs the generated data signal to an external device.

The imaging unit may output the generated image signal to the controller 30, instead of to the external device. The controller 30 may output the captured image signal input from the imaging unit as a data signal to the display panel 12 to display the captured image.

For instance, a flexible material such as a polycarbonate film may be used as the substrate of the display panel 12. The bezel 14 may be omitted, whereby the display panel 12 is foldable. The omission of the bezel 14 contributes also to miniaturization and weight reduction of the display panel 12 or the display device 10.

The above mainly describes the examples where each pixel has three light emitting elements, and the present invention is not limited to this. The number of light emitting elements in each pixel may be one, two, or four or more. For instance, the individual pixels may be monochrome pixels that represent luminance and not chromaticity. In that case, a single light emitting elements in each pixel suffices.

The display device 10 may be part of an information processing apparatus. The information processing apparatus includes a control unit as well as the display device 10. For instance, the control unit includes an arithmetic processor. For instance, the arithmetic processor is a CPU. The control unit may output a data signal acquired by itself to the display device 10 and display an image based on the data signal on the display panel 12. The control unit may generate the data signal or obtain it from an external device. The control unit may cause the imaging unit to capture an image and acquire an image signal indicating the captured image. The control unit may cause the imaging unit to capture an image in response to an operation signal input from the input device in accordance with a user's operation. The control unit may execute commands described in a given program to control the process such as displaying images on the display panel 12, capturing images for the imaging unit, and generating, receiving, and reading images to be displayed or captured. The information processing apparatus may be implemented in any form such as a personal computer, a multifunctional mobile phone (including a smart phone), or a tablet terminal.

As described above, the display panel 12 in the above embodiments has a substrate and a plurality of pixels (e.g., pixel px), with one or more light emitting elements (e.g., light emitting elements sr, sg, sb) per pixel. The plurality of pixels are placed at different positions on the surface of the substrate. The pixels are placed so that the occupancy rate of light emitting elements is lower in the first region RA, which is part of the substrate surface, than in the second region PA, which is the region surrounding the first region RA, and in the second region PA, the occupancy rate of light emitting elements is higher at positions further away from the first region RA.

Typically, under a certain luminance per area, the higher the occupancy rate of light emitting elements, the higher the luminance of the screen. With this configuration, the screen luminance becomes higher the further away from the first region RA is, which mitigates an abrupt change in luminance at the boundary between the first region RA and the second region PA. As a result, this configuration mitigates or eliminates the degradation of image quality due to changes in luminance.

In the second region PA, pixels located farther from the first region RA may have larger light emitting elements. This configuration increases the luminance of the screen at positions farther from the first region RA, even if the pixel density is the same between the first region RA and the second region PA. The pixels are placed at regular intervals, whereby the light emission timing for each pixel can be easily determined according to the location of that pixel.

In the second region PA, pixels located farther from the first region RA may have higher density.

This configuration increases the luminance of the screen at positions farther from the first region RA, even if the size of light emitting elements is the same between the first region RA and the second region PA. This eliminates the necessity of pixels with light emitting elements of different sizes.

The display panel 12 in the above embodiments has a substrate and a plurality of pixels, and has one or more light emitting elements and a drive element per pixel, and the drive element supplies current to the light emitting elements. The plurality of pixels are placed at different positions on the surface of the substrate. The pixels are placed so that the occupancy rate of light emitting elements is lower in the first region RA, which is part of the substrate surface, than in the second region PA, which is the region surrounding the first region RA. The drive element (e.g., light-emitting element driving transistor 56) for the light emitting element of a pixel located in the first region RA supplies more current than the drive element for the light emitting element of a pixel located in the second region PA.

Typically, a light emitting device emits light with higher luminance the higher the current flowing through it. With this configuration, under a constant luminance value, the light emitting elements of the pixels located in the first region RA emit light with higher luminance than the light emitting elements of the pixels located in the second region PA. This configuration allows the density of light emitting elements in the first region RA to be lower than the density of light emitting elements in the second region PA, and mitigates or eliminates a decrease in luminance in the first region RA.

The aspect ratio W/L of the width W to the length L of the drive elements for the light emitting elements of the pixels located in the first region RA may be greater than the aspect ratio W/L of the drive elements for the light emitting elements of the pixels located in the second region PA.

For signal voltage V_{sig} corresponding to a certain luminance value, this configuration allows more current to flow through the light emitting elements of the pixels located in the first region RA than through the light emitting elements of the pixels located in the second region PA. The light emitting elements of the pixels located in the first region RA emit light with higher luminance than the light emitting elements of the pixels located in the second region PA. This means that the density of light emitting elements in the first region RA may be lower than that in the second region PA, and the configuration mitigates or eliminates a decrease in luminance in the first region RA.

The light emitting elements described above may be organic light emitting diodes (OLEDs).

These elements achieve a wide range of luminance in accordance with the current flowing through them, and realize an image with high contrast. They do not require a backlight for light emission, so that the display panel can be thin and flexible.

The display panel 12 described above may further include an imaging unit (e.g., a camera 20) on the back surface of the first region RA to be configured as the display device 10.

An information processing apparatus (not illustrated, e.g., PC, smartphone, and tablet terminal) may have the display device 10 and a control unit (e.g., CPU) that outputs a data signal indicating a luminance value for each pixel to the display panel 12. The control unit is able to control whether or not the camera 20 needs to shoot.

That is detailed descriptions on the embodiments of the present invention with reference to the drawings, and the specific configuration of the present invention is not limited to the above-described embodiments, and the present invention also includes design modifications or the like within the scope of the present invention. The configurations described in the above embodiments can be combined freely.

### DESCRIPTION OF SYMBOLS

10 display device
12 display panel
14 bezel
20 camera
30 controller
40 input interface
50 pixel circuit
58 (sr, sg, sb) light emitting element
RA first region
PA second region
SA transition region
NA standard region
px pixel

What is claimed is:

1. A display panel comprising:
a substrate having a surface, and a plurality of pixels; and
one or more light emitting elements for each pixel,
the plurality of pixels being placed at different positions on the surface of the substrate,
the pixels being disposed so that an occupancy rate of the light emitting elements is lower in a first region, which is part of the surface of the substrate, than in a second region, which is a region surrounding the first region and so that in the second region, the occupancy rate increases with a distance from the first region.

2. The display panel according to claim 1, wherein in the second region, the light emitting elements located farther from the first region have a larger size.

3. The display panel according to claim 1, wherein in the second region, the pixels located farther from the first region have a higher density.

4. A display panel comprising:
a substrate having a surface, and a plurality of pixels; and
one or more light emitting elements and a drive element in each pixel, the drive element being configured to supply current to the one or more light emitting elements, the plurality of pixels being placed at different positions on the surface of the substrate,
the pixels being placed so that an occupancy rate of the light emitting elements is lower in a first region, which is part of the surface of the substrate, than in a second region, which is a region surrounding the first region,
the drive elements for the light emitting elements are configured to supply more current for the light emitting elements of the pixels located in the first region than for the light emitting elements of the pixels located in the second region.

5. The display panel according to claim 4, wherein an aspect ratio of a width to a length of the drive elements for the light emitting elements of the pixels located in the first region are greater than the aspect ratio of the drive elements for the light emitting elements of the pixels located in the second region.

6. The display panel according to claim 1, wherein the light emitting elements include organic light emitting diodes.

7. A display device comprising:
the display panel according to claim 1; and
an imaging unit configured to capture an image on a back surface of the first region.

8. An information processing apparatus comprising:
the display device according to claim 7; and
a control unit configured to cause the display device to output an image in accordance with a data signal indicating a luminance value for each pixel and cause the imaging unit to capture an image.

9. The display panel according to claim 4, wherein the light emitting elements include organic light emitting diodes.

10. A display device comprising:
the display panel according to claim 4; and
an imaging unit configured to capture an image on a back surface of the first region.

11. An information processing apparatus comprising:
the display device according to claim 10; and
a control unit configured to cause the display device to output an image in accordance with a data signal indicating a luminance value for each pixel and cause the imaging unit to capture an image.
